(19) United States
(12) Patent Application Publication
(10) Pub. No.: US 2024/0170303 A1
(43) Pub. Date: May 23, 2024

(54) INTERCONNECT ALIGNMENT SYSTEM AND METHOD

(71) Applicant: SAMTEC, INC., New Albany, IN (US)

(72) Inventors: John CORONATI, New Albany, IN (US); Marc EPITAUX, New Albany, IN (US); Brandon Thomas GORE, New Albany, IN (US)

(21) Appl. No.: 18/552,463

(22) PCT Filed: Mar. 30, 2022
(86) PCT No.: PCT/US2022/022686

§ 371 Date: Sep. 26, 2023

Related U.S. Application Data
(60) Provisional application No. 63/168,030, filed on Mar. 30, 2021.

(51) Int. Cl. H01L 21/60; H01L 21/48

(52) U.S. Cl. CPC H01L 21/60; H01L 21/485; H01L 2021/6003; H01L 2021/60075

(57) ABSTRACT

An interconnection system includes a mating substrate that is configured to be placed in electrical communication with a main board along an insertion direction so as to define a separable interface. The interconnection system is configured to align the mating substrate with the main board along first and second transverse directions that are perpendicular to each other and to the insertion direction.

### CROSS-REFERENCE TO RELATED APPLICATIONS

This claims the benefit of U.S. Patent Application Ser. No. 63/168,030 filed Mar. 30, 2021, the disclosure of which is hereby incorporated by reference as if set forth in its entirety herein.

### BACKGROUND

Modern electronics components, such as microprocessors, FPGA (field programmable gate arrays), ASIC (application specific integrated circuits) and other such devices, often require many, for example, greater than 1000, input/output (I/O) electrical connections. These electrical components generally consist of a semiconductor die mounted to and electrically attached to a die substrate or equivalently an IC (integrated circuit) package substrate. In order to maintain a reasonably small package size for the component, the electrical contacts associated with each of these independent electrical connections must be closely spaced on the IC package. The contacts are often situated on a side of the IC substrate opposite the die and arranged in a square or rectangular grid. The pitch between adjacent contacts may be less than 1 mm and in some cases less than 0.5 mm.

Electrical systems often employ optical links to transport data between electrical processing elements. To improve the high bandwidth operation of these links it is desirable to place the optical-to-electrical (O/E) or electrical-to-optical (E/O) conversion components close to the electrical processing element to minimize the length of electrical transmission and maximize the length of optical transmission. These E/O and O/E components may likewise require small contact pitches between adjacent electrical contacts to minimize the overall package size.

Rather than permanently attaching an electrical, E/O, or O/E component to a main or host substrate or printed circuit board (PCB), using solder or some other means, it is often desirable to have a separable interconnection, so the component can be installed after other components are soldered to the main board or easily replaced if desired. This is particularly important for E/O and O/E components where optical fiber breakage issues and an inability to withstand solder reflow temperatures make permanently attaching the element undesirable. Alignment of the IC substrate to its mating interface must have a tolerance significantly less than the contact pitch, for example, less than 20% of the contact pitch, otherwise not all electrical connections will be made as desired. This is a challenge as the pitch size become smaller.

In order to obtain electrical contact at the separable interface one or both of the contacts on opposite sides of the interface typically elastically deform as the two sides of the separable interface are mated. A restoring force produced by the elastic deformation urges contacts on opposing sides of the separable interface together resulting in an electrical connection. In most prior art interconnection systems, a least one contact was formed by a metal finger that would bend during mating. The metal finger was formed by stamping a metal sheet or photolithographically defining the finger for smaller pitch applications. However, it is challenging to fabricate a large array of metal fingers that are small enough and have sufficient strength and compliance for current and future generations high density interconnects.

Additionally, at least some of the interconnections must be capable of transmitting high bandwidth data streams, such as signals have a data transfer rate in excess of 1 Gbps (Gigabits per second), with good signal integrity. Generally making the interconnection path length short and minimizing abrupt changes in the geometry of the signal transmission path facilitate high bandwidth operation.

There is a need for an interconnection system that can provide a separable electrical interface for an electrical, E/O, or O/E component having a dense array of electrical contacts.

### SUMMARY

In one example, a method of preparing a food product can include the steps of providing a mixture of batch food product, cooking the mixture of batch food product such that the food product defines a cooked batch food product, and cooling the cooked batch food product, such that the cooked batch food product defines a cooled food product. The method can further include, after the cooling step, the step of dosing the cooled food product with a cannabinoid.

### BRIEF DESCRIPTION OF FIGURES

FIG. 1 is a perspective view of a data communication system including plurality of optical modules mounted to an ASIC package substrate in one example;

FIG. 2 is a cross-sectional view an interconnection system in one example;

FIG. 3 is a cross-sectional view of the interconnection system of FIG. 2 with a mating substrate installed;

FIG. 4 is a cross-sectional view an interconnection system in another example.

FIG. 5 is a cross-sectional view of the interconnection system of FIG. 4 with a mating substrate installed;

FIG. 6 is a cross-sectional view an interconnection system in still another example;

FIG. 7 is a cross-sectional view of the interconnection system of FIG. 6 with a mating substrate installed;

FIG. 8 is a perspective view of a frame of the interconnection system of FIG. 6;

FIG. 9 is a cross-sectional view an interconnection system according in yet another example;

FIG. 10 is a cross-sectional view of the interconnection system of FIG. 9 with a mating substrate installed.

FIG. 11 is a cross-sectional view an interconnection system in still another example; and

FIG. 12 is a cross-sectional view of the interconnection system of FIG. 11 with a mating substrate installed.

### DETAILED DESCRIPTION

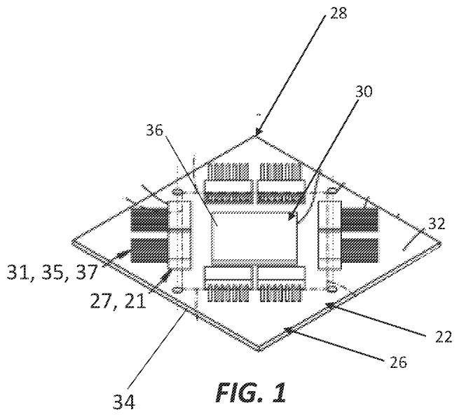

With reference to FIGS. 1-8 generally, a separable interconnection system 20 is provided between a main board 22 and a mating substrate 24. The mating substrate 24 may be an IC package substrate 26 of an IC package 28 that includes the IC package substrate 26 and a semiconductor die 30 mounted to the IC package substrate 26. The semiconductor die 30 can be mounted on a top or first substrate surface 32 of the IC package substrate 26 that is opposite a bottom or second surface 34 of the mating substrate 24. An upward direction, and the term “above,” is thus defined as a direction from the bottom surface 34 toward the top surface 32. Conversely, a downward direction, and the term “below,” is defined as a direction from the top surface 32 toward the bottom surface 34. The terms “top” and “bottom” as used herein with respect to surfaces of a component are used with reference to the upward direction and the downward direction unless otherwise indicated. The IC semiconductor can be configured as an IC die 36. The IC die 36 can be an ASIC as desired. The bottom surface 34 of the IC package substrate 26 may be referred to as a mating interface, since the bottom surface 34 of the mating substrate 24 supports electrically conductive elements that make electrical contact with an adjacent electrically conductive element across a separable interface when the mating substrate 24 is mated to the main board 22. The main board 22 may be considered a host board or mother board. The main board 22 may have a socket 38 mounted to it which is configured to accept the mating substrate. 24 For instance, the socket 38 can be permanently mounted to the main board 22. In some embodiments, no socket is required.

The mating substrate 24 can be connected to the main board 22 through an electrical interconnect member 40. The electrical interconnect member 40 can be configured as an anisotropically conductive compliant contact layer in some examples. In other examples the electrical interconnect member can be constructed in any manner desired having electrically conductive elements that are disposed between the main board 22 and the mating substrate 24 so as to place the main board 22 in electrical communication with the mating substrate 24 when the mating substrate 24 is mated with the main board 22. In one example, the electrically conductive elements can be configured as fuzz buttons, electrical conductors, or other suitable electrically conductive elements as desired. The electrical interconnect member 40 can be arranged as a layer that is oriented along the first and second transverse directions T1 and T2.

The mating substrate 24 may also be part of an optical-to-electrical conversion component, an electrical-to-optical conversion components or a combined optical-to-electrical and electrical-to-optical conversion component. Collectively a component that performs these conversion functions may be described as an optical module 27 that can send and/or receive optical signals from an optical fiber 31. A bottom surface of the optical module may have a mating substrate on its bottom surface. The optical module may have an optical fiber pigtail or it may be connectorized to accept an optical fiber connector. The mating substrate may be configured to mate with the top surface 32 of the IC package substrate 26. The IC package 28 may have one or more electrical components as described above, such as the IC die 36, mounted on the top surface 32 of the IC package substrate 26. In this example, the IC package substrate 26 may be described as the main board 22 or in other examples the mating substrate 24. FIG. 1 is a perspective view of a separable interconnection system 20 including a plurality of optical modules 22 separably mounted on a top surface 24 of an IC package 26 that surrounds a central IC die 28. Any suitable hardware can compress the optical module into the IC package substrate and a socket that may be mounted to the top surface of the IC package substrate as desired.

The mating substrate 24 may also be part of a cable connector 21 suitable for transmitting high speed electrical signals, such as greater than 28 gigabits per second, and in some examples at least 56 gigabits per second. The cable connector 21 may have a mating substrate on its bottom surface. Contacts exposed on the mating substrate are permanently connected by solder or some other means to conductive wires in an electrical cable or flex circuit that terminates in the cable connector 21. The mating substrate 24 may be configured to mate with the top surface 32 of the IC package substrate 26. The IC package 28 may have one or more electrical components mounted on the top surface 32 of the IC package substrate. In this example, the IC package substrate 26 may be described as the main board. This embodiment is depicted in FIG. 1 by replacing the optical module with the cable connector 29, and replacing the optical fiber 31 with an electrical cable 37 or flex circuit 35.

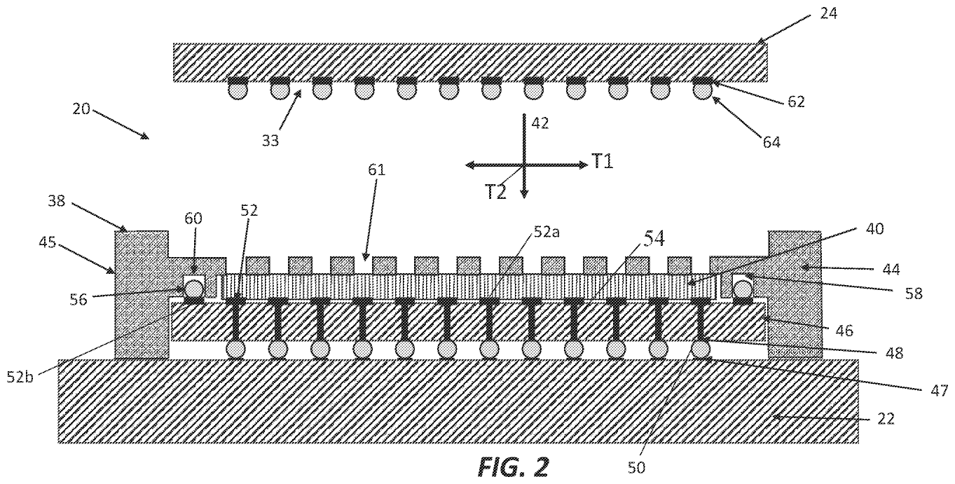

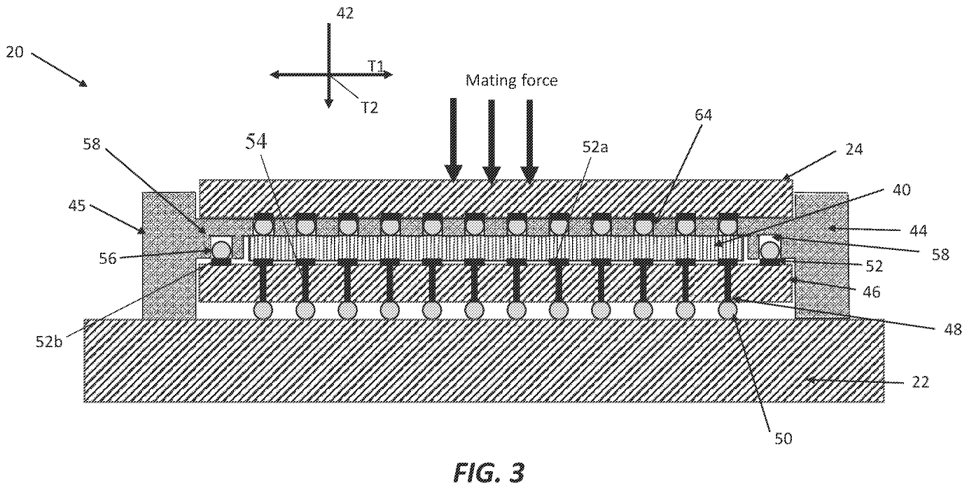

Referring now to FIGS. 2-3, the interconnection system 20 according to a first example provides a separable electrical and mechanical interface between the main board 22 and the mating substrate 24. FIG. 2 shows the mating substrate 24 separated from the main board 22 along an insertion direction 42, and FIG. 3 shows the mating substrate 24 mated with the main board 22. The insertion direction 42 can be aligned with the upward direction and the downward direction. The mating substrate 24 is precisely aligned with the main board 22 in a first transverse direction T1 and a second transverse direction T2, that are perpendicular to each other and to the insertion direction 42, thereby ensuring a reliable electrical connection between the mating substrate 24 and the main board 22 through the electrical interconnect member 40.

The interconnection system 20 may include an interposer 46 that can be mounted to the main board 22, and a frame 44 mechanically coupled to the interposer 46 to define the socket 38. The frame can be mounted coupled to the main board 22 as desired. The main board 22, the frame 44, and the interposer 46 can combine to define a main board assembly 45. The mating substrate 24 can be mated to the main board assembly 45 at a separable interface so as to establish an electrical connection with the main board 22. The socket 38 may be electrically and mechanically permanently connected to the main board 22. The main board 22 may be a printed circuit board (PCB), a printed wiring assembly (PWA), an ASIC package substrate, or any substantially rigid, flat element having electrical contacts. The main board 22 may also be called a host substrate, mother board or other such term. Electrical connections between the socket 38 and the main board 22 may be formed by reflowing solder to provide an electrical connection between electrically conductive main board lands 47 on a top or first surface of the main board 22 and electrical interposer contacts 48 located at a bottom or second surface of the interposer 46. Solder balls 50 may be attached to the electrical interposer contacts 48, thereby forming a ball grid array (BGA). The solder balls 50 may be formed from SAC305 solder, which is a mixture of tin, gold, and copper although other types of solders may be used. By reflowing the solder balls 50, the interposer 46 may be permanently mounted to the main board 22. The solder reflow process tends to automatically align the main board lands 47 with the electrical interposer contacts 48, since when the solder 50 is liquid surface tension tends to minimize the surface area of the solder urging the main board lands 47 and electrical interposer contacts 48 into alignment with each other along the insertion direction.

A plurality of electrically conductive interposer lands 52 may be disposed at a top or first surface of the interposer 46 forming a land gird array (LGA). The top surface is opposite a bottom or second surface of the interposer 46. Some of the interposer lands 52, referred to as electrical lands 52a, serve an electrical function and some of the lands 52, referred to as mechanical lands 52b, serve only a mechanical alignment function. Thus, electrical signals do not travel through the mechanical lands 52b between the mating substrate 24 and the main board 24. In contrast, electrical signals travel through the electrical lands 52a as they are transmitted between the mating substrate 24 and the main board 22. The lands 52 may be arranged in a rectangular array. The electrical lands 52a may be positioned directly above the bottom electrical interposer contacts 48 and electrically connected to the electrical contacts 48 by an array of through vias 54. The mechanical lands 52b may be positioned outside along the perimeter of the array of electrical lands 52a. The electrical lands 52a and mechanical lands 52b may be formed during the same processing step to ensure accurate registration between the mechanical and electrical lands. If the lands 52 are formed through a photolithographic process, the alignment tolerance between the lands 52 may be on the order of ±5 microns. The electrical lands 52a may be arranged on a rectangular grid have a pitch in the range of approximately 0.2 to 0.8 mm in the two transverse directions. Smaller pitches are possible. The alignment accuracy of the mechanical and electrical lands may be less than 5%, 10% 20%, or 25% of the pitch between the electrical lands 52a. Each electrical land 52a may be a square or round metal pad having a side length or diameter approximately ½ of the pitch. The mechanical lands 52b may be the same size, smaller, or larger than the electrical lands 52a. The mechanical lands 52b are preferably round and may have a diameter in the range of 200 to 500 microns, but can have any suitable alternative shape as desired.

Each of the mechanical lands 52b may have a respective interposer alignment feature 56 attached to them. The interposer alignment feature 56 may be a small element, such as a sphere, cylinder, cube, pyramid, disk, etc., attached to the mechanical land using a solder reflow process or it may be simply a solder ball. For example, the interposer alignment feature may be a slumped solder ball that has been reflowed on the land or a gold-plated stainless-steel sphere or disk that has been bonded to the mechanical land by solder reflow. Advantageously the solder reflow process with cause the interposer alignment feature 56 to automatically align with the mechanical land 52b. The interposer 46 may have a square or rectangular shape, or any suitable alternative shape as desired. The alignment feature 56 can be a mechanical alignment feature, and is not electrically connected to either of the main board 22 and the mating substrate 24.

The frame 44 may surround the interposer 46 on all sides of the interposer 46 in a plane that is defined by the first and second transverse directions T1 and T2. When the interposer 46 defines a square or rectangle in the plane that includes the first and second transverse directions T1 and T2, the frame 44 can surround all four sides of the interposer 46. The frame 44 has at least one frame alignment guide 58 such as a plurality of frame alignment guides 58 that register with mating interposer alignment features 56 so as to align the mating substrate 22 for mating with the main board assembly 45 along the insertion direction 42. The frame alignment guides 58 may define of an alignment hole 60 that extends at least into a bottom surface of the frame 44. Thus, the alignment hole 60 can have an opening at the bottom surface of the frame 44 so that the interposer alignment feature 56 fits inside the alignment hole 60. Interference between the interposer alignment feature 56 and one or more of the side walls that define the alignment hole 60 can substantially prevent movement of the frame 44 with respect to the interposer 46 in either or both of the first and second transverse directions T1 and T2. The frame 44 may have a plurality of alignment holes 60 arranged on a regular grid, such as a rectangular grid. When the frame 44 is aligned with the interposer 46, the alignment holes 60 may be situated above respective ones of the electrical interposer lands 52. The frame 44 can be fabricated from an electrically insulative material. The frame 44 may be formed from a liquid crystal polymer or any other suitable insulative material.

The main board assembly 45, and thus the separable interconnection system 20, can include the electrical interconnect member 40 that is configured to be placed in electrical communication with the interposer lands 52, and can further be placed in electrical communication with the mating substrate 24 when the mating substrate is mated with the main board assembly 45. The electrical interconnect member 40 can be received by the frame 44. In one example, the electrical interconnect member 40 can be an anisotropically conductive compliant contact layer. The anisotropically conductive compliant contact layer has a plurality of electrically conductive channels that extend between an upper and opposed lower surface of the anisotropically conductive compliant contact layer. At least one channel contacts every electrical land on the top or first surface of the interposer. The at least one channel extends to an opening in the frame. The anisotropically conductive compliant contact layer may be a PariPoser® conductive member available from Paricon Technologies of Taunton, MA. A PariPoser® consists of many small electrically conductive channels formed from a vertically extending column of conductive balls supported by an elastomeric matrix. As the PariPoser® is depressed the conductive column can deform in response to the applied force while maintaining a low impedance electrical path between the top and bottom balls of a column. Each column is electrically isolated from adjacent columns. The thickness of the anisotropically conductive compliant contact layer may be in the range of approximately 25 to 500 microns. The anisotropically conductive compliant contact layer may elastically deform by 10 to 150 microns in response to an applied compressive mating force applied to the interconnection region.

It is known to use a PariPoser® as an electrical interconnect between two planar substrates having arrays of electrical contacts. One advantage of using a PariPoser® is that it does not need to be precisely aligned between the planar substrates along the two transverse directions, since the spacing between the electrically conductive columns is less than the spacing between adjacent contacts. Independent of the exact position of the PariPoser® one or more conductive columns extend from the interposer electrical land to the opening.

The minimum amount of deformation of the anisotropically conductive compliant contact layer should be sufficient to compensate for non-planarity of any of the surfaces at the mating interface so that mechanical contact is made between the top of the anisotropically conductive compliant contact layer and all electrical contacts on the bottom of the mating substrate and between the bottom of the anisotropically conductive compliant contact layer and all electrical contacts on the top of the main board. The deformation should also be sufficient that the restoring elastic force at all contact areas is sufficient to establish a low resistance electrical path for all contacts across the mating interface. As such, more deformation and a thicker anisotropically conductive compliant contact layer may be used with larger mating substrates and less deformation and a thinner anisotropically conductive compliant contact layer may be used with smaller mating substrates. Mating substrates with an IC die may be an example of a large substrate, with package dimensions in the range of 100 mm in the two transverse directions. An example of a small mating substrates may be a mating substrate that is part of an optical module having a package dimension less than 20 mm in the two transverse directions.

The electrical interconnect member 40, and in particular the anisotropic conductive compliant contact is not limited to use of a PariPoser® member. For example, an array of compressible, electrically conductive columns may be formed by embedding separate tangled bundles of small diameter wire in an array of holes in an insulative matrix. Such an array of separate tangled bundle of small diameter wire is available Custom Interconnects, LLC, Centennial, CO (sold as Fuzz Button® technology) or Bel Group, Lombard, IL (sold as CIN::ASPE® technology). Conductive fibers can also be used, as described in U.S. Pat. No. 10,720,398, along with other approaches. U.S. Pat. No. 10,720,398 is hereby incorporated by reference as if set forth in its entirety herein.

The socket 38 can be configured to accept and receive the mating substrate 24 that is inserted into the socket 38 in the insertion direction. The mating substrate 24 may have a plurality of mating substrate lands 62 on its bottom or second surface, which forms a mating interface 33 of the mating substrate 24. All or most of the mating substrate lands 62 may have mating substrate alignment features 63 attached to them. The mating substrate alignment features 63 may be a small element, such as a sphere, cylinder, cube, pyramid, disk, or the like. In one example, the mating substrate alignment features 63 can be solder balls 64. As previously disclosed, the mating substrate 24 may be an IC (integrated circuit) package that has an IC die 36 mounted on top of an IC package substrate 26. The mating substrate 24 may also be a daughter card, part of an optical module, or part of a cable connector terminating a mating flex circuit or high speed electrical cables.

FIG. 3 shows a cross-sectional view of the mating substrate inserted into the socket of FIG. 2. The interposer alignment features 56 are captured by the frame alignment guides 58, respectively, to align the frame 44 to the interposer 46 in the first and second transverse directions T1 and T2. By aligning the interposer alignment features 56 with the frame alignment guides 58 along the insertion direction, upper frame alignment members such as top openings 61 in the frame 44 are arranged to align with the solder balls 64 or other alignment members supported by the bottom of the mating substrate 24 as the mating substrate 24 is inserted into the socket 38. The solder balls 64 or other alignment members thus fit through the upper openings 61 of the frame 44 and may contact the top or first surface of the electrical interconnect member 40. The openings 60 of the frame can be referred to as bottom openings. In some examples, the electrical interconnect member 40 can deform in response to the mating force, which is applied to a top or first surface of the mating substrate 22. The mating force may be provided by a clamp mounted to the frame or by an alternative mechanical fastener. Deformation of the electrical interconnect member 40 can produce a low impedance separable electrical interface between the electrically conductive elements of the electrical interconnect member 40 and the solder balls 64 supported by the mating substrate 24. The separable electrical connection between the mating substrate 24 and the electrical interconnect member 40 allows the mating substrate 24 to be electrically connected to the main board 22. The mating substrate 24 may be removed from the socket 38 at the separably interface without desoldering any component or without special tools.

Thus, it should be appreciated that engagement of the interposer alignment features 56 and the frame alignment guides 58 can align the frame 44 with the interposer 46, and thus with the main board 22 to which the interposer 46 is mounted. Engagement of the mating substrate alignment members with the upper frame alignment members can align the mating substrate 22 with the frame 44. Because the frame 44 is aligned with the main board 22, the mating substrate 22 is similarly aligned with the main board 22.

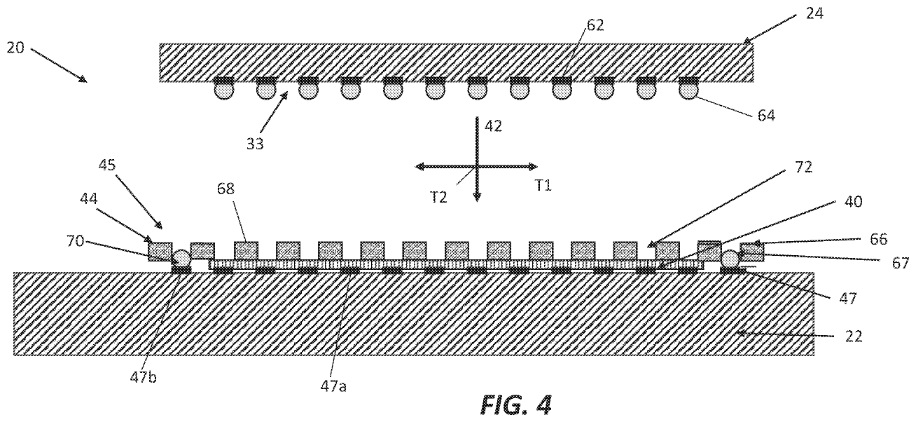

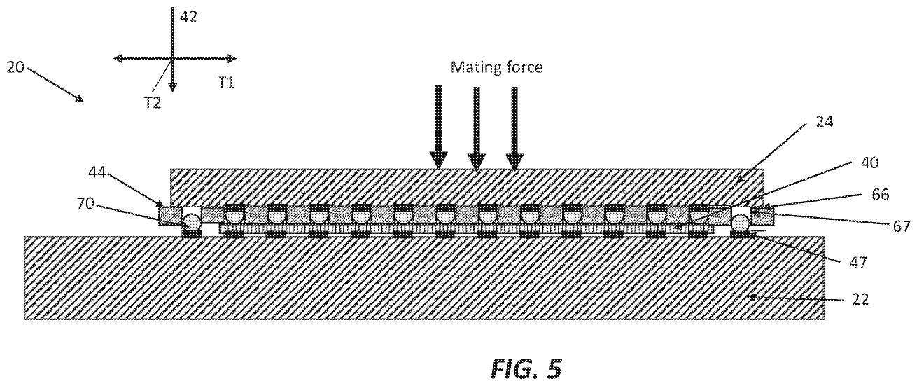

FIGS. 4-5 show cross-sectional views of the interconnection system 20 in another example. The interconnection system 20 provides a separable electrical and mechanical interface between the main board 22 and the mating substrate 24. FIG. 4 shows the mating substrate 24 separated from the main board 22 along an insertion direction, and FIG. 5 shows the mating substrate 24 mated with the main board 22. The mating substrate 24 can be precisely aligned in the first transverse direction T1 and the second transverse direction T2 that are perpendicular to each other and perpendicular to the insertion direction.

The mating substrate 24, main board 22, and the electrical interconnect member 40 of FIGS. 4 and 5 may be similar or identical to that shown in FIGS. 2 and 3.

In contrast to the embodiment depicted in FIGS. 2-3, the frame 44 of the interconnection system 20, and in particular the main board assembly 45, can be defined by an electrically insulative alignment sheet 66. The alignment sheet can be a Kapton sheet or Kapton tape in some examples. In one example, the alignment sheet 66 can extend along a plane that is defined by the first transverse direction T1 and the second transverse direction T2. The alignment sheet 66 can define a sheet body 68 and a plurality of precisely aligned holes 72 that extend through the alignment sheet 66 along the insertion direction 42. The alignment sheet 66 may be fabricated from polyimide, liquid crystal polymer, polytetrafluoroethylene or some other suitable electrically insulative material. The alignment sheet material may have low dielectric losses at electromagnetic frequencies in the 1 GHz to 1 THz range.

The main board 22 may have electrically conductive lands 47 that can include electrical lands 47a, which serve an electrical function as described above with respect to the electrical lands 52a of FIGS. 2-3, and mechanical lands 47b, such as at least two mechanical lands 47b, which serve only a mechanical alignment function as described above with respect to the mechanical lands 52b of FIGS. 2-3. Thus, electrical signals travel through the electrical lands 47a, and don't travel through the mechanical lands 47b. The electrical lands 47a may be arranged in a rectangular grid in the transverse directions T1 and T2, and the mechanical lands 47b may be located outside of the grid. The main board 22 can include at least one main board alignment feature 70, such as at least two main board alignment features 70, supported by the main board 22 that may be attached to respective ones of the mechanical lands 47. The main board alignment feature and attachment method may be similar to that previously described for the interposer alignment feature and will not be repeated here.

In one example, the main board alignment features 70 can be configured as solder balls 50 that do not transmit electrical signals during operation. The electrical interconnect member 40 can be disposed on the top surface of the main board 22 and is in electrical contact with the electrical main board lands 47a located on the top surface of the main board 22. The alignment sheet 66 is disposed above the electrical interconnect member 40. The alignment sheet 66 may have a thickness in the range of approximately 150 to 500 microns. The alignment sheet 66 can define a sheet alignment guide 67 that can include a plurality of sheet alignment members that can be configured as the holes 72. The holes 72 can be configured as through holes extend through the alignment sheet 66 along the insertion direction 42 as desired. The holes 72 can be aligned with the electrical lands 47a of the main board along the insertion direction 42. Registration between the holes and sheet alignment guides is tightly controlled. During operation, the main board alignment feature 70 can be received in respective bottom ends of respective ones of the holes 72. The solder balls 64 of the mating substrate 24 can be received in others of the holes 72. The others of the holes 72 can define a grid that is defined by the first and second transverse directions T1 and T2, and the ones of the holes can be disposed outside the grid.

FIG. 5 shows a cross-sectional view of the mating substrate 24 inserted into the main board assembly 45 of FIG. 4. The main board alignment features 70 are captured by the sheet alignment guides 67 to align the main board 22 with the alignment sheet 66 in the two transverse directions T1 and T2. Therefore, the holes 72 of the alignment sheet 66 are configured to aligned with the solder balls 64 supported by the bottom of the mating substrate 22 as the mating substrate is inserted into the alignment sheet 66 along the insertion direction 42. The solder balls 64 thus fit through the alignment sheet 66 and may contact the top surface of the electrical interconnect member 40. The electrical interconnect member 40. may deform in response to the mating force in some examples, which is applied to the mating substrate 24. The mating force may be provided by a clamp mounted to the main board 22 or by some other mechanical fastener. Deformation of the electrical interconnect member 40 can provide a low impedance electrical contact between the electrically conductive elements of the electrical interconnect member 40 and the solder balls 64 supported by the bottom of the mating substrate 24. The separable electrical connection so formed allows the mating substrate 24 to be electrically connected to and disconnected from the main board 22.

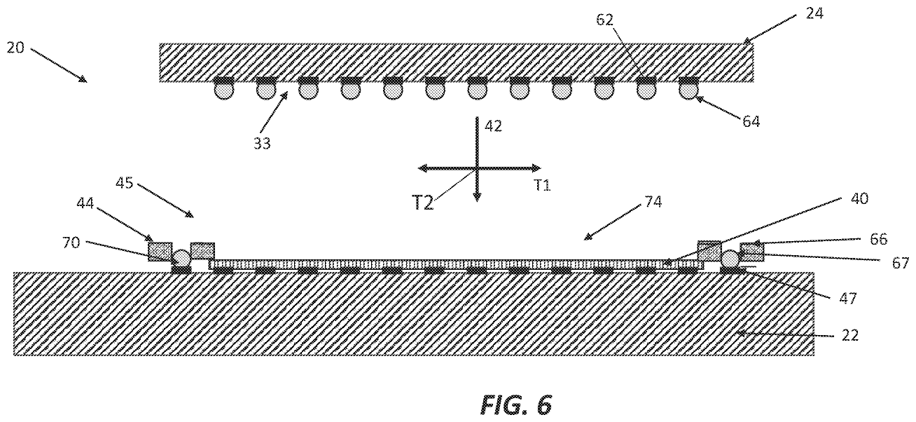

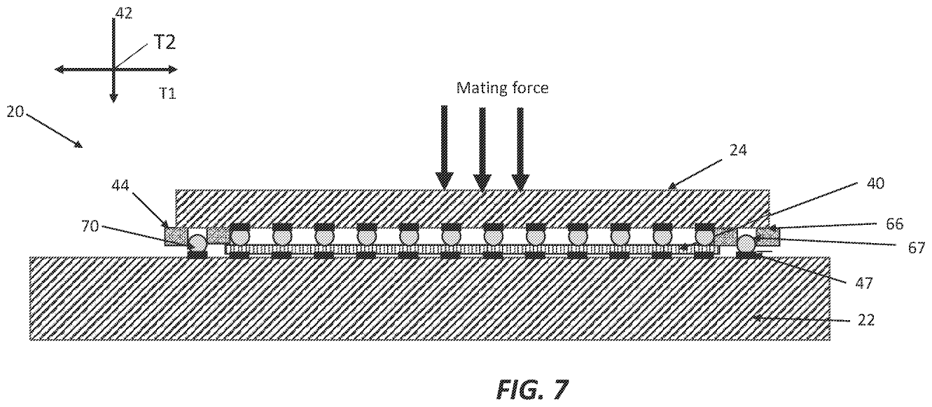

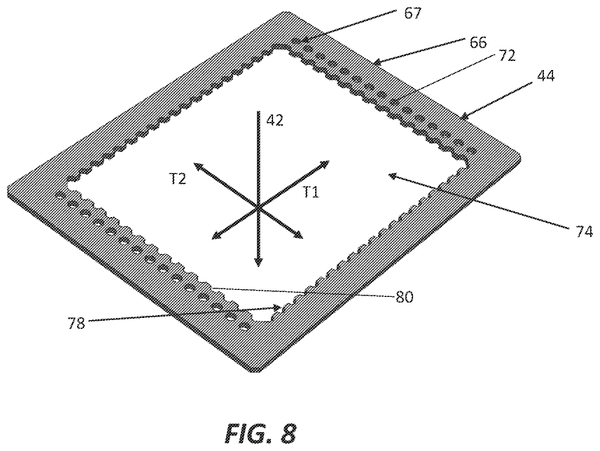

FIGS. 6 and 7 show cross-sectional views of an interconnection system 20 in another example. FIG. 8 shows a perspective view of the frame 44 of FIGS. 6-7. The interconnection system 20 provides a separable electrical and mechanical interface between the main board 22 and the mating substrate 24. FIG. 6 shows the mating substrate 24 separated from the main board 22 along an insertion direction 42, and FIG. 7 shows the mating substrate 24 mated with the main board 22. The mating substrate 24 is precisely aligned in a first transverse direction T1 and a second transverse direction T2 that are orthogonal to each other and perpendicular to the insertion direction 42.

This embodiment is similar to that described previously and depicted in FIGS. 4 and 5, but the plurality of openings 72 in the frame 44 that receive the solder balls 64 of the mating substrate 24 are replaced by a single central hole 74 that extends through the frame 72. In this regard, the frame 44 can include at least one opening that receives more than one solder ball 64 of the mating substrate 24. In some examples, the frame 44 can include a plurality of openings that each receives more than one solder ball 64 of the mating substrate 24. As illustrated in FIGS. 6-8, the single central hole 74 can receive all solder balls 64 of the mating substrate 24 that are configured to support electrical signal transfer.

The frame 44 can be configured as the alignment sheet 66 of electrically insulating material. The alignment sheet 66, and thus the frame 44, can have at least one such as at least two sheet alignment guides 67 than can define holes 72. In FIG. 8 the at least two sheet alignment guides 67 are two rows of 72 holes on opposed sides of the frame along the first transverse direction T1. The rows of holes 72 can be oriented along the second transverse direction T2. In other versions of this embodiment the sheet alignment guide 67 may be a single hole 72 on each side of the frame rather than a row of holes. Four sheet alignment guides 67 may also be used, one situated near each corner of the frame. The sheet alignment guides 67 need not be present on all sides of the sheet 66 but should be present on at least two opposing sides. The arrangement of the sheet alignment guides is not limited to any of the above examples.

The frame 44 has a large hole 74 in a central portion of the frame 44. Around the periphery of the central opening are at least two mating substrate alignment guides 78. The mating substrate alignment guides 78 are a series of indentations 80 along at least one such as a pair such as all sides of the central hole 74. In other versions of this embodiment the mating substrate guide 78 may be a single indentation 80 on each side of the frame 44 rather than a row of indentations. Four mating substrate alignment guides 78 may also be used, one at or near the center of each side of the central hole 74. Rather than indentations, the mating substrate alignment guides 78 may be holes that extend at least into or through the frame 44. The mating substrate alignment guides 78 need not be present on all sides of the sheet but should be present on at least two opposing sides. The arrangement of the mating substrate guides 78 is not limited to any of the above examples. Registration between the mating substrate alignment guides 78 and sheet alignment guides 67 is tightly controlled.

FIG. 7 shows a cross-sectional view of the mating substrate inserted into the interconnection system of FIG. 6. The main board alignment features 70 are captured in the sheet alignment guides 67 to align the sheet 66 to the main board 22 in the two transverse directions T1 and T2. By aligning the main board alignment features 70 with the sheet alignment guides 67, the sheet 66 is placed in a predetermined correct position with respect to the two transverse directions T1 and T2. The mating substrate 22 may then be inserted into the central hole 74 in the sheet along the insertion direction 42. The mating substrate alignment guides 78 are arranged to align with the solder balls 64 of the mating substrate 24, such that the solder balls 64 are received in the central hole 74 when the mating substrate 24 is inserted into the alignment sheet along the insertion direction 42. The solder balls 64 can thus make physical and electrical contact with the electrically conductive elements, respectively, of the electrical interconnect member 40, through the sheet 66. The electrical interconnect member 40 is in electrical communication with the main board 22 in the manner described above. Thus, the mating substrate 22 is placed in electrical communication with the main board 22. As described above, the electrical interconnect member 40 may deform in response to the mating force, which is applied to the mating substrate. The mating force may be provided by a clamp mounted to the main board or by some other mechanical structure. Deformation of the electrical interconnect member 40 can provide a low impedance electrical contact between the conductive columns in the anisotropically conductive compliant contact layer and the solder balls 64 on the bottom of the mating substrate 24. The separable electrical connection so formed allows the mating substrate 24 to be electrically connected to the main board 22.

As described above, the solder balls 64 can be arranged in a grid that is defined by the transverse directions T1 and T2. The solder balls 64 at the perimeter of the grid can contact an inner surface of the frame 44 that defines the central hole 74. The mating substrate alignment guides 78 can position the solder balls 64 at the perimeter of the grid in respective ones of the recesses 80 so that the mating substrate 24 is fixed at a predetermined desired position with respect to the frame 44 in the transverse directions T1 and T2.

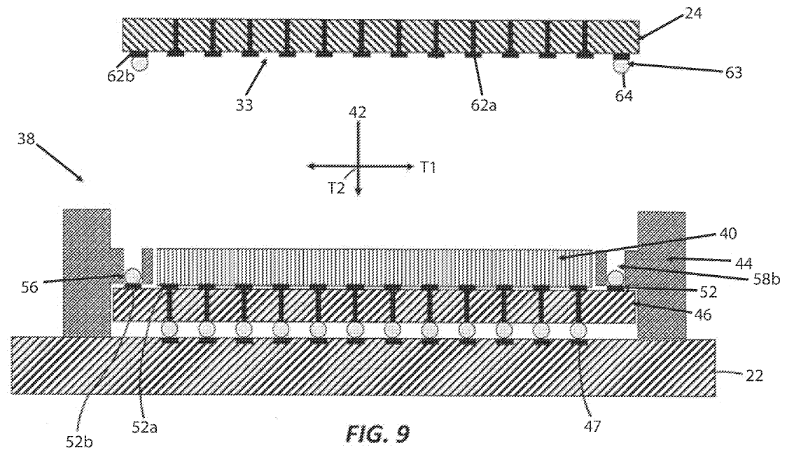

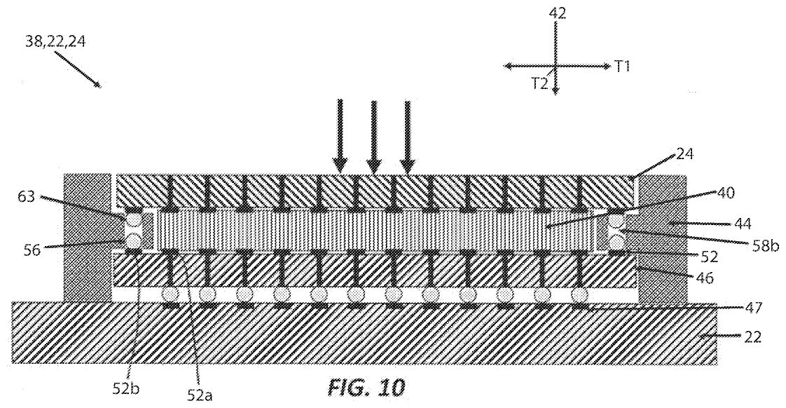

Referring now to FIGS. 9-10, the interconnection system 20 can be configured in accordance with yet another example. The interconnection system 20 provides a separable electrical and mechanical interface between the main board 22 and the mating substrate 24. FIG. 9 shows the mating substrate 24 separated from the main board 22 along the insertion direction 42, and FIG. 10 shows the mating substrate 24 mated with the main board 22. The mating substrate 24 is aligned in the first and second transverse directions T1 and T2.

The fourth embodiment depicted in FIGS. 9 and 10 is similar to the first embodiment depicted in FIGS. 2 and 3 in both embodiments, the frame 44 can surround the interposer 46. The arrangement of the main board 22, main board lands 47, interposer 46, and electrical interconnect member 40 may be as described above with respect to FIGS. 2 and 3. In this embodiment, the electrical lands 62 of the mating substrate 24 can include at least one electrical land 62a such as a plurality of electrical lands 62a that serve an electrical function of the type described above, and at least one mechanical land 62b such as a plurality of mechanical lands 62b that serve only a mechanical alignment function of the type described above. Thus, electrical signals travel through the electrical lands 62a, and don't travel through the mechanical lands 62b. The at least one mechanical land 62b may have a respective at least one mating substrate alignment feature 63 attached to it. The mating substrate alignment feature 63 may be a small element, such as a sphere, cylinder, cube, pyramid, disk, etc., attached to the mating substrate using a solder reflow process or it may be simply a solder ball. For example, the mating substrate alignment feature may be a slumped solder ball 64 that has been reflowed on the land or a gold-plated stainless-steel sphere or disk that has been bonded to the mechanical land 62b by solder reflow. There can be at least two mechanical lands 62b and alignment features 63 attached to the bottom of the mating substrate. The mating substrate alignment features may be positioned outside of an array of the electrical lands in the first and second transverse directions T1 and T2.

As in the first embodiment, the frame 44 may have an alignment guide 58 configured as a through hole that extends through the frame 44. As shown in FIG. 10, the frame alignment guide 44 can engage both the interposer alignment feature 56 and the mating substrate alignment feature 63 with respect to the first and second transverse directions T1 and T2. Thus, the interposer alignment feature 56 and the mating substrate alignment feature 63 can be aligned with each other along the insertion direction 62. In particular, respective pairs of the interposer alignment feature 56 and the mating substrate alignment features 63 can be received in respective common through holes of the frame 44 that define the frame alignment guides 58. This arrangement differs from that described with respect to FIGS. 2-3, in which the alignment guide 58 of the frame 44 aligns the interposer alignment features 56 and the mating substrate alignment features 63 in respective different holes. In particular, the mating substrate alignment features are received in top holes of the frame 44, and the interposer alignment features 56 are received in different bottom holes of the frame 44 that can be offset from the top holes in either or both of the first and second transverse directions T1 and T2, or in an oblique direction that includes the first and second transverse directions T1 and T2. As described above with respect to the other examples, a mating force may be applied to the top of the mating substrate 22 to urge the mating substrate 22 towards the main board 24 as desired to maintain electrical connectivity at the separable interface.

In one example, the interposer alignment feature 56 and the mating substrate alignment feature 63 can be made of different materials, and can thus have different melting temperatures. Further, the solder balls 50 of the main board 22 can have a lower melting temperature than the interposer alignment features 56, such that the interposer alignment feature does not reflow during reflow of the solder balls 50 of the main board. Alternatively or additionally, the lands 52b can be made of a first material that the solder balls 56 will adhere to, and an anti-wicking second material that surrounds the first material, so that the solder of the solder ball 56 does not wick along the land 52b along the first and/or second transverse directions T1 and T2.

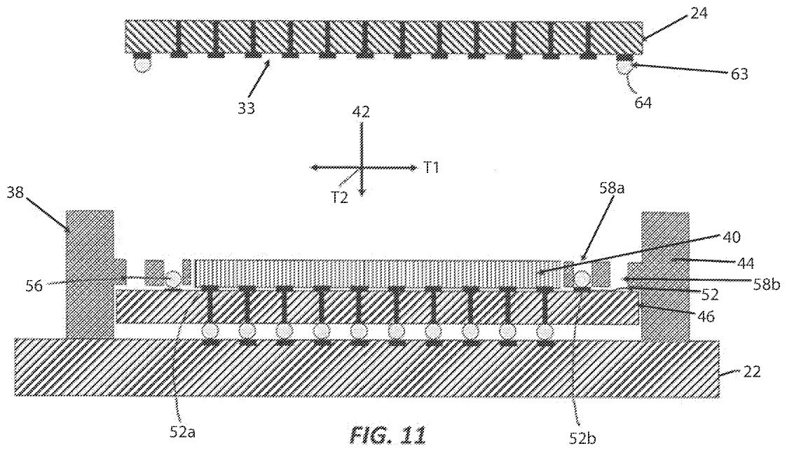

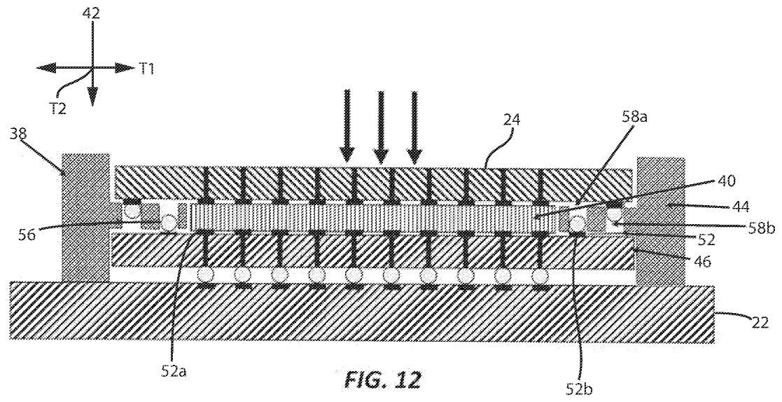

FIGS. 11 and 12 show cross-sectional views of the interconnection system 20 according to a still another example. The interconnection system 22 can provide a separable electrical and mechanical interface between the main board 22 and the mating substrate 24. FIG. 11 shows the mating substrate 24 separated from the main board 22 along the insertion direction 42, and FIG. 12 shows the mating substrate 24 mated with the main board 22. The mating substrate 24 can be precisely aligned in the first and second transverse directions T1 and T2.

Much of the interconnect system 20 of FIGS. 11-12 are similar to the interconnect system of FIGS. 6-8, such that differences between the two examples of the interconnect system 20 will now be described. In particular, as shown in FIG. 11, the frame can have a first alignment guide 58a and a second alignment guide 58b. At least one or more first alignment guides 58a are configured to register with a respective at least one or more alignment features 56 of the interposer 46. At least one or more second alignment guides 58b are configured to register with a respective at least one or more mating substrate alignment features 63. For instance, the first and second alignment guides 58a and 58b can be configured as holes that extend at least into or through the frame 44. For instance, the first alignment guides 58a can extend downward at least into the top surface of the frame 44 along the insertion direction 42. The second alignment guides can extend upward at least into the bottom surface of the frame 44. The first and second alignment guides 58a and 58b can be configured to receive alignment features 56 of the interposer 46 and the mating substrate alignment features 58b, respectively.

Thus, the first and second alignment guides 58a and 58b are configured to position the mating substrate 22 at a desired position relative to the interposer 46 with respect to the first and second transverse directions T1 and T2. Because the interposer 46 is electrically connected to the main board 22, the first and second alignment guides 58a and 58b therefore position the mating substrate 24 in a desired position relative to the main board 22 with respect to the first and second transverse directions T1 and T2. Thus, the mating substrate 24 can be placed in reliable electrical communication with the main substrate 22 through the electrical interconnect member 40 and the interposer 46. The first alignment guides 58a may be referred to as interposer alignment guides. The second alignment guides 58b may be referred to as mating substrate alignment guides. In FIGS. 11 and 12 the first and second alignment guides 58a and 58b can be offset from each other along the first transverse direction T1. In other examples, the first and second alignment guides 58a and 58b can be offset from each other in the second transverse direction T2 or an oblique direction that includes a combination of the first and second transverse directions T1 and T2. The alignment guides 58a and 58b may have identical interior dimensions, or the alignment guides may have different sizes.

One advantage of the frame 44 of FIGS. 11-12 is that the interposer alignment features 56 and the mating substrate alignment features 63 are not aligned with each other along the insertion direction 42 when they are received by the respective alignment guides 58 of the frame 44. This may allow the electrical interconnect member 40 to be thinner and/or the interposer alignment feature and mating substrate alignment feature to be larger.

The examples described herein may be used whenever a separable interface is desired between a mating substrate and main board. As described above both the mating substrate and main board can take many forms. Having a separable interface provides for easy replacement of the mating substrate with a new mating substrate, and whatever is attached to the mating substrate, should the need arise. The examples described herein also allow the mating substrate to be attached to the main board after all other components have been soldered to the main board to form the main board assembly 45. The mating substrate and any associated components thus are not subjected to solder reflow temperatures which may damage the mating substrate or any associated components.

In another application of the interconnection system, the mating substrate may be a bare semiconductor die. The die has a plurality of lands on its bottom surface. At least two of these lands have an alignment feature attached to them, preferably using a solder reflow process. The alignment features are configured to position the die in a socket when the die is mated to the socket. The socket may include a frame and an interposer. The interposer may include a redistribution layer that changes the contact pitch between a top and bottom side of the interposer. Contacts on the top side of the interposer, adjacent the die lands, may be more closely spaced than contacts on the bottom side. The socket is attached to a main board that may be part of a test apparatus configured to test the bare die. Because of the redistribution layer in the socket, lands on the main board may have a larger pitch than lands on the die. In this application the die would be mated to the main board for only a short period of time for diagnostic testing. Once the diagnostic testing has been completed the die may be unmated from the interconnection system and another die can be temporarily mated to the main board for testing.

The terms “upward,” “upper,” “up,” “above,” and derivatives thereof are used herein with reference to the upward direction. The terms “downward,” “lower,” “down,” “below,” and derivatives thereof are used herein with reference to the downward direction. Of course, it should be appreciated that the actual orientation of the optical interconnection system shown in FIGS. 2 through 9 can vary during use, and that the terms upward and downward and their respective derivatives can be consistently used as described herein regardless of the orientation of the interconnection system thereof during use. Similarly use of the term “top” and “bottom” refers to an orientation as depicted in the figures and may not reflect the orientation of these surfaces in actual use. Thus, the term “top” can also be referred to as “outer” and the term “bottom” can also be referred to as “inner” as desired. Inner surfaces are spaced from respective outer surfaces of the components described herein along an inward direction, and outer surfaces are spaced from respective inner surfaces of the components described herein along an outward direction.

It should be appreciated that the illustrations and discussions of the embodiments shown in the figures are for exemplary purposes only and should not be construed limiting the disclosure. One skilled in the art will appreciate that the present disclosure contemplates various embodiments. For example, the invention is generally described in terms of using solder balls at one or more of the electrical interfaces; however, this is not a requirement. Other interconnection methods such as copper pillars, may be used in place of or in addition to solder balls. In some embodiments, the electrical interconnect member 40 is shown contacting a land on one side of the layer and a solder ball on the opposing side. The electrical interconnect member 40 may contact lands on both side, solder balls on both sides, or some attachment feature other than solder balls on one or both sides. While the electrical lands and mechanical lands were described as having distinct functions, an electrical land may serve a mechanical alignment function in addition to an electrical function and a mechanical land may serve an electrical function in addition to a mechanical alignment function. The arrangement of the various described alignment features may be rearranged as desired. For example, FIGS. 4 and 5 illustrate an interposer with mechanical lands and the mating substrate as having electrical lands. This arrangement may be inverted so that the interposer has electrical lands and the mating substrate has mechanical lands. In some embodiments, it may be possible to have no mechanical lands, with at least some of the electrical lands serving a mechanical alignment function in addition to their electrical function. In any embodiment, the interposer may include a redistribution layer to alter the spacing between contacts on the top and bottom surfaces of the interposer. Additionally, it should be understood that the concepts described above with the above-described embodiments may be employed alone or in combination with any of the other embodiments described above. It should be further appreciated that the various alternative embodiments described above with respect to one illustrated embodiment can apply to all embodiments as described herein, unless otherwise indicated.

1. A main board assembly comprising:
an interposer having an array of lands arranged in a grid on a first surface of the interposer, wherein a plurality of lands are electrical lands that serve an electrical function and at least two of the lands are mechanical lands that serve only a mechanical alignment function, each of the at least two mechanical lands having an attached interposer alignment feature;
an electrical interconnect member that makes electrical contact with at least some of the electrical lands;
a frame that receives the electrical interconnect member, the frame having at least two alignment guides, each guide having a respective one of the interposer alignment features positioned in the guide.

2. The main board assembly as recited in claim 1, wherein the frame surrounds the interposer and the electrical interconnect member.

3. The main board assembly as recited in claim 1, wherein the at least two alignment guides are arranged to receive at least two mating substrate alignment features that are attached to at least two lands on a mating interface of a mating substrate.

4. The main board assembly as recited in claim 1, wherein the frame further comprises at least two mating substrate alignment guides arranged to receive at least two mating substrate alignment features that are attached to at least two lands on a mating interface of a mating substrate.

5. An interconnection system comprising an interposer that defines a first surface and a second surface, solder balls at the second surface that are mounted to a main board, and solder balls at the first surface that aligned with a frame that, in turn, aligns with a mating substrate, wherein the solder balls at the first surface provide only a mechanical alignment function.

6. The interconnection system of claim 5, wherein the frame is configured to align with the mating substrate, such that the mating substrate is aligned with the main board.

7. An interconnection system that provides a separable electrical connection between a main board and a mating substrate comprising:
at least one main board alignment feature supported by the main board,
an electrical interconnect member in electrical contact with an array of electrical lands of the main board, wherein the electrical lands are arranged in a grid defined by first and second perpendicular transverse directions; and
an electrically insulative sheet having a plurality of holes, wherein the at least one main board alignment feature can be received in a respective one of the holes, and a respective other of the holes is configured to receive a mating substrate alignment feature of the mating substrate.

8. The interconnection system of claim 7, wherein the respective one of the holes comprises a plurality of holes arranged in a grid defined by the first and second transverse directions, and the respective other of the holes is disposed outside the grid.

9. The interconnection system of claim 7, wherein the respective one of the holes aligns the main board relative to the electrically insulative sheet with respect to the first and second transverse directions, and the respective other of the holes aligns the mating substrate relative to the electrically insulative sheet with respect to the first and second transverse directions.

10. The interconnection system of claim 7, wherein the at least one main board alignment feature is mounted to electrically conductive lands of the main board.

11. The interconnection system of claim 7, wherein the sheet defines a single hole that receives a plurality of solder balls of the mating substrate.

12. The interconnection system of claim 11, wherein the single hole receives all solder balls of the mating substrate.

13. The interconnection system of claim 11, wherein the sheet defines recesses at an inner surface that defines the holes, and outer solder balls of the mating substrate are received in respective ones of the recesses so as to align the mating substrate with the sheet.

14. The interconnection system of claim 7, wherein the sheet comprises a polyimide sheet.

15. An interconnection system that provides a separable electrical connection between a main board and a mating substrate comprising:
a mating substrate alignment feature attached to mechanical lands located on a first surface of the mating substrate;
an electrical interconnect member mounted to the main board; and
an electrical insulative sheet having an array of openings arranged in a grid, wherein at least some of the openings in the array are aligned with the electrical lands on the first surface of the mating substrate.

16. The interconnection system of claim 15, wherein the mating substrate alignment feature comprises at least two mating substrate alignment features.

17. An interconnection system that provides a separable electrical connection between a main board and a mating substrate comprising:
an electrical interconnect member that makes electrical contact with an array of electrical lands arranged in a grid disposed on the first surface of the main board; and
an electrical insulative sheet having a central opening, wherein the perimeter of the central opening has a mating substrate alignment guide.

18. The interconnection system of claim 17, wherein the mating substrate alignment guide comprises at least two mating substrate alignment guides.

19. The interconnection system of claim 1, wherein the electrical interconnect member comprises an anisotropically conductive compliant contact layer.

20. The interconnection system of claim 17, wherein the electrical interconnect member comprises an anisotropically conductive compliant contact layer.
